(19) United States
(12) Patent Application Publication
(10) Pub. No.: US 2022/0235453 A1
(43) Pub. Date: Jul. 28, 2022

(54) COMMON VACUUM SHUTTER AND PASTING MECHANISM FOR A MULTISTATION CLUSTER PLATFORM

(71) Applicant: Applied Materials, Inc., Santa Clara, CA (US)

(72) Inventors: Kirankumar Neelasandra SAVANDAIAH, Bangalore (IN); Nagabhushana NANJUNDAPPA, Bangalore (IN); Srinivasa Rao YEDLA, Bangalore (IN); Thomas BREZOCZKY, Los Gatos, CA (US)

(21) Appl. No.: 17/159,689

(22) Filed: Jan. 27, 2021

(51) Int. Cl. C23C 14/56; H01L 21/67; H01L 21/687; C23C 14/34; C23C 14/50; C23C 14/35; H01J 37/32; H01J 37/34

(52) U.S. Cl. CPC C23C 14/568; H01L 21/67167; H01L 21/68707; H01L 21/67259; C23C 14/3407; H01J 2237/332; C23C 14/35; H01J 37/32899; H01J 37/32733; H01J 37/3405; H01J 37/3423; C23C 14/505

(57) ABSTRACT

A substrate processing module includes a transfer chamber, an array of processing stations, at least one shutter disk assembly, and a substrate handling device. The array of processing stations is disposed within a transfer volume, and each of the processing stations within the array are configured to selectively process at least one substrate. The shutter disk assembly includes an actuator and a disk blade configured to support a shutter disk coupled thereto. The shutter disk is rotatable between a first position and a second position. In the first position, the disk blade is disposed between two of the plurality of processing stations. In the second position, the disk blade is located under one of the processing stations within the array. The substrate handling device is disposed centrally within the transfer volume and includes a plurality of arms each configured to support and position a substrate.

### BACKGROUND

### Field

Embodiments of the present disclosure generally relate to an apparatus and a method and, more specifically, to a substrate processing module and a method of moving multiple shutter disks within a substrate processing module.

### Description of the Related Art

Conventional cluster tools are configured to perform one or more processes during substrate processing. For example, a cluster tool can include a physical vapor deposition (PVD) chamber to perform a PVD process on a substrate, an atomic layer deposition (ALD) chamber for performing an ALD process on a substrate, a chemical vapor deposition (CVD) chamber for performing a CVD process on a substrate, and/or one or more other processing chambers.

The aforementioned cluster tools include transfer systems to move workpieces, such as substrates or shutter disks, to and from various processing chambers within the system. For example, carousel systems with multiple arms are used to grasp either substrates or shutter discs. Rotating the carousel system moves the workpieces in and out of the various processing chambers in the cluster tool. The carousel typically has different grasping arms with different form and function, depending on the desired workpiece to be grasped.

One drawback in the art is that, in cluster tools with more than one processing station chamber, each processing station chamber may require a different frequency of burn in and/or pasting processing to occur between performing a PVD process on a substrate. Whenever one of the multiple processing station chambers requires a target burn in and/or pasting, all of the wafers being processed in each processing chamber must be removed from the cluster tool by the transfer system, and a shutter disk must be transferred into the cluster tool to the processing chamber to be burned in or pasted. Accordingly, this independent chamber process involves breaking the vacuum of the cluster tool and reduces the productivity of the system.

Therefore, what is needed is a multi-shutter disk assembly within the cluster tool that can allow for independent chamber target burn-in and/or pasting for each processing chamber without breaking the vacuum or removing the workpieces from the cluster tool.

### SUMMARY

Embodiments disclosed herein include a substrate processing module and a method of operating a multi-shutter disk assembly. The substrate processing module and method allow for moving a shutter disk between a processing module and a storage area within the substrate processing module.

In one embodiment, a substrate processing module is provided. The substrate processing module includes a transfer chamber, an array of processing stations, at least one shutter disk assembly, and a substrate handling device. The transfer chamber has a side wall and a bottom which defines a transfer volume. The array of processing stations is disposed within the transfer volume, and each of the processing stations within the array are configured to selectively process at least one substrate. The shutter disk assembly is disposed in the transfer volume. The shutter disk assembly includes an actuator and a disk blade. The disk blade is coupled to the actuator and configured to support a shutter disk. The actuator is configured to rotate the disk blade between a first position and a second position. The substrate handling device is disposed centrally within the transfer volume. The substrate handling device includes a plurality of arms each configured to support and position a substrate under the processing stations within the array. When the disk blade is in the first position, the disk blade is disposed between two of the plurality of processing stations. When the disk blade is in the second position, the disk blade is located under one of the processing stations within the array.

In another embodiment, a substrate processing module is provided. The substrate processing module includes a transfer chamber, a first processing assembly, and a substrate handling device. The transfer chamber has a sidewall and a bottom which defines a transfer volume. The first processing assembly is disposed within the transfer volume and comprises a first substrate processing station, a first shutter disk assembly, a first shutter disk storage area, and a first plurality of sensors. The first shutter disk assembly is disposed near the first substrate processing station. The first shutter disk assembly comprises an actuator and a disk blade coupled to the actuator. The first disk blade is rotatable between a first position within the shutter disk storage area and a second position located under the first substrate processing station. The first shutter disk storage area is disposed near the shutter disk assembly and configured to house the disk blade and a shutter disk disposed thereon. The first plurality of sensors are positioned to determine a rotational position of the shutter disk blade. The substrate handling device is disposed centrally within the transfer volume and includes a plurality of arms each configured to position a substrate under the substrate processing station.

In yet another embodiment, a method of processing substrates is provided. The method includes first placing a plurality of substrates within an array of processing stations disposed within a substrate processing module. Next, the method includes performing a physical vapor deposition process on the plurality of substrates within the array of processing station. Next, the method includes moving the plurality of substrates from the processing stations of the array using a substrate handling device. Next, the method includes rotating at least one of a plurality of shutter disk assemblies from a first position to a second position. The first position of each shutter disk assembly is located within a plurality of shutter disk storage areas disposed within the substrate processing module. The second position is below at least one of the processing stations. Next, the method includes performing a second process in at least one of the processing stations. Finally, the method includes rotating at least one of the shutter disk assemblies from the second position to the first position.

### BRIEF DESCRIPTION OF THE DRAWINGS

So that the manner in which the above recited features of the present disclosure can be understood in detail, a more particular description of the disclosure, briefly summarized above, may be had by reference to the embodiments, some of which are illustrated in the appended drawings. It is to be noted, however, that the appended drawings illustrate only exemplary embodiments and are therefore not to be considered limiting of its scope, and the disclosure may admit to other equally effective embodiments.

FIGS. 1A-1B are plan views of a cluster tool assembly according to certain embodiments.

FIGS. 2A-2B are schematic cross sectional views of a processing module according to certain embodiments.

FIGS. 3A-3B are partial top isometric views of processing modules according to certain embodiments.

FIG. 4A is a top isometric view of a shutter disk assembly, according to certain embodiments.

FIG. 4B is a top view of a shutter disk blade of the shutter disk assembly of FIG. 4A, according to certain embodiments.

FIGS. 5A-5B are partial top views of a processing module according to certain embodiments.

FIG. 6 is a method of moving a plurality of shutter disks within a processing module, according to certain embodiments.

FIGS. 7A-7B are top cross sectional views of a processing module according to certain embodiments.

FIGS. 8A and 8B side views of a sensor assembly disposed beneath the processing module of FIGS. 7A and 7B, according to certain embodiments.

To facilitate understanding, identical reference numerals have been used, where possible, to designate identical elements that are common to the Figures. It is contemplated that elements and features of one embodiment may be beneficially incorporated in other embodiments without further recitation.

### DETAILED DESCRIPTION

The present disclosure generally relates to a substrate processing module and method of operating multiple shutter disk assemblies within the substrate processing module. The substrate processing module includes an array of processing stations, a plurality of shutter disk assemblies, and a substrate handling device. The method of operating multiple shutter disk assemblies includes performing a physical vapor deposition (PVD) process on a substrate within a processing station, moving the substrate from the processing station, and moving a shutter disk assembly between a first position and a second position below the processing station. The substrate processing module and method allows for selectively moving a substrate between the various processing stations within the array and selectively rotating a shutter disk disposed on the shutter disk assembly between a shutter disk storage position and a position below one of the processing stations.

The multiple shutter disk assemblies within the substrate processing module allow for each processing volume to be selectively operated without the need to break the vacuum within the substrate processing module. Advantageously, having a shutter disk assembly for each processing station within substrate processing module enables more selective processing of a substrate by allowing the operator to perform independent substrate processes, such as a PVD process or a burn-in or pasting process, at each of the processing stations within the array.

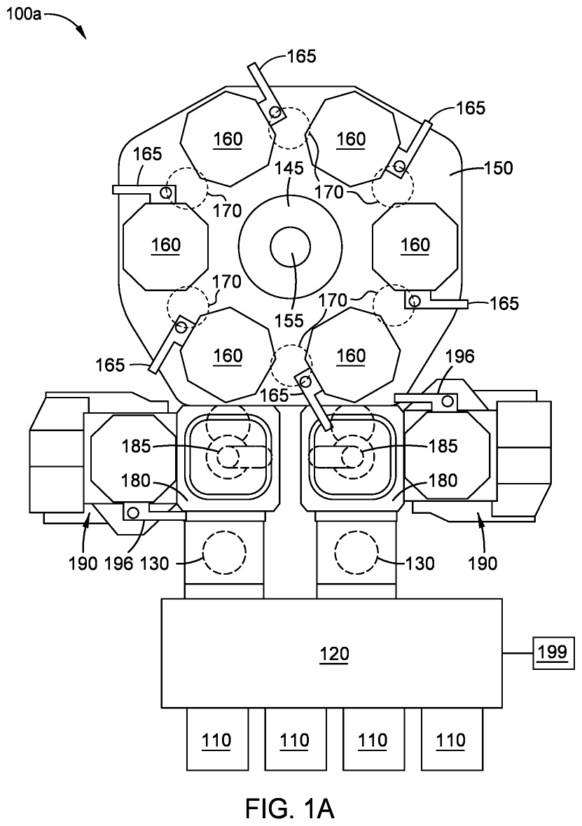

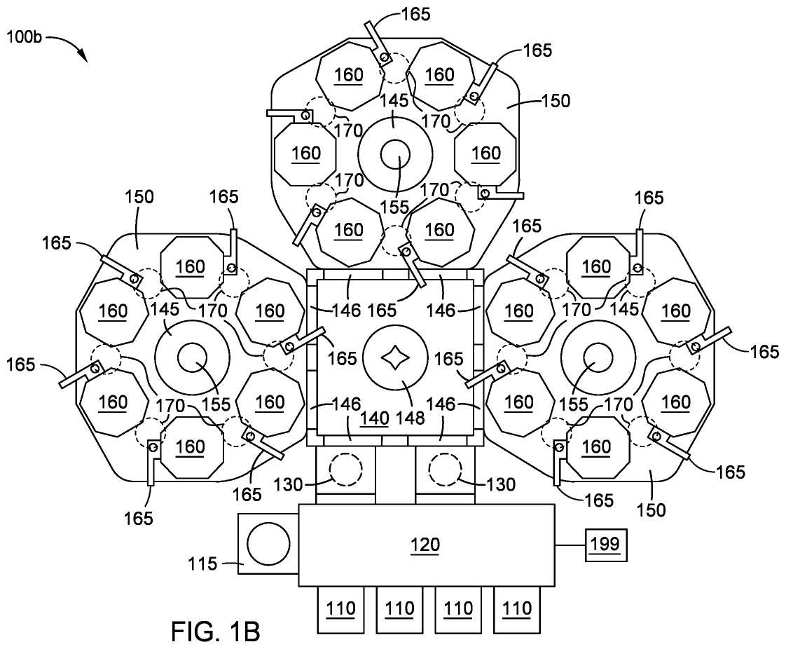

A processing system, such as processing system 100 of FIGS. 1A and 1B, is used to form one or more thin films on the surface of a substrate and/or, on a layer previously formed or processed on the substrate. FIGS. 1A-1B are plan views of cluster tool assemblies 100a, 100b with processing modules 150 and processing stations 160A-F as described herein. The cluster tool assembly 100a of FIG. 1A includes a single processing module 150 and a plurality of front end robot chambers 180 between the processing module 150 and load lock chambers 130. The cluster tool assembly 100b of FIG. 1B includes multiple transfer chamber assemblies 150 and a buffer chamber 140 disposed between the processing modules 150 and the load lock chambers 130.

In FIG. 1A, the cluster tool assembly 100a includes a cassette or Front Opening Unified Pods (FOUPs) 110 (four shown), which are located within or connected to a sidewall of a factory interface (FI) 120. The cluster tool assembly 100a includes one or more load lock chambers 130 (two shown), which are adjacent to and operably connected to the FI 120. The FOUPs 110 are utilized to safely secure and store substrates during movement thereof between different substrate processing equipment, as well as during the connection of the FOUPs to the substrate processing equipment while the substrates are disposed therein.

The cluster tool assembly 100a further includes one or more front end robot chambers 180 (two shown), which are adjacent to and operatively connected to the load lock chambers 130 and one or more prep chambers 190 adjacent to and operatively connected to the front end robot chambers 180. The front end robot chambers 180 are located on the same side of each of the load lock chambers 130, such that the load lock chambers 130 are located between the FI 120 and the front end robot chambers 180. The front end robot chambers 180 each include a transfer robot 185 therein. The transfer robot 185 is any robot suitable to transfer one or more substrates from one chamber to another, through or via the front end robot chamber 180. In some embodiments, as shown in FIG. 1A, the transfer robot 185 within each front end robot chamber 180 is configured to transport substrates from one of the load lock chambers 130 and into one of the prep chambers 190.

The prep chambers 190 may be any one of a pre-clean chamber, an anneal chamber, or a cool down chamber, depending upon the desired process within the cluster tool assembly 100a. In some embodiments, the prep chambers 190 are plasma clean chambers. In yet other exemplary embodiments, the prep chambers 190 are Preclean II chambers available from Applied Materials, Inc. of Santa Clara, Calif. A vacuum pump 196 is positioned adjacent to each of the prep chambers 190. The vacuum pumps 196 are configured to pump the prep chambers 190 to a predetermined pressure. In some embodiments, the vacuum pumps 196 are configured to decrease the pressure of the prep chamber 190, such as to create a vacuum within the prep chamber 190.

As shown in FIG. 1A, two load lock chambers 130, two front end robot chambers 180, and two prep chambers 190 are configured within the cluster tool assembly 100a. The two load lock chambers 130, the two front end robot chambers 180, and the two prep chambers 190, when arranged as shown in FIG. 1A and described above, may form two transport assemblies. The two transport assemblies may be spaced from each other and may form mirror images of one another, such that the prep chambers 190 are on opposite walls of their respective front end robot chambers 180. Each of the load lock chambers 130 and front end robot chambers 180 are configured to pass substrates from the FI 120 into the processing module 150, as well as from the processing module 150 and into the FI 120.

The process module 150 is adjacent to, and operatively connected to, the front end robot chambers 180, such that substrates are transferred between the processing module 150 and front end robot chambers 180. The processing module 150 includes a substrate handling device 145 and an array of processing stations 160 therein. In certain embodiments, the array of processing assemblies 160 are disposed circumferentially around the substrate handling device 145, radially outward of a pivot or central axis of the substrate handling device 145 in the processing module 150.

A chamber pump 165 is disposed adjacent to, and in fluid communication with, each of the processing stations 160, such that there are a plurality of chamber pumps 165 disposed around the substrate handling device 145. The plurality of chamber pumps 165 are disposed radially outward of the substrate handling device 145 in the processing module 150. As shown in FIG. 1A, one chamber pump 165 is fluidly coupled to each of the processing stations 160. In some embodiments, there may be multiple chambers pumps 165 fluidly coupled to each processing station 160. In yet other embodiments, one or more of the processing stations 160 may not have a chamber pump 165 directly fluidly coupled thereto. The chamber pumps 165 enable separate vacuum pumping of the processing regions within each processing station 160, and thus the pressure within each of the processing stations 160 may be maintained separately from one another and separately from the pressure present in the processing module 150.

FIG. 1A depicts an embodiment having six processing stations 160 within the processing module 150. However, other embodiments have a different number of processing stations disposed within the processing module 150. For example, in some embodiments, two to twelve processing stations may be positioned within the processing module 150, such as four to eight processing stations 160. In other embodiments, four processing stations 160 may be positioned within the processing module 150. The number of processing stations 160 impact the total footprint of the cluster tool 100a, the number of possible process steps capable of being performed by the cluster tool 100a, the total fabrication of the cluster tool 100a, the throughput of the cluster tool 100a, and, as to be discussed further herein, the number of shutter disk assemblies 170 disposed within the processing module 150.

Each of the processing stations 160 can be any one of PVD, chemical vapor deposition (CVD), atomic layer deposition (ALD), etch, cleaning, heating, annealing, and/or polishing platforms. In some embodiments, the processing stations 160 are all one type of processing platform, such as a PVD platform. In other embodiments, the processing stations 160 include two or more different processing platforms. In one exemplary embodiment, all of the processing stations 160 are PVD process chambers. The array of processing stations 160 may be altered to match the types of process stations needed to complete a semiconductor fabrication process.

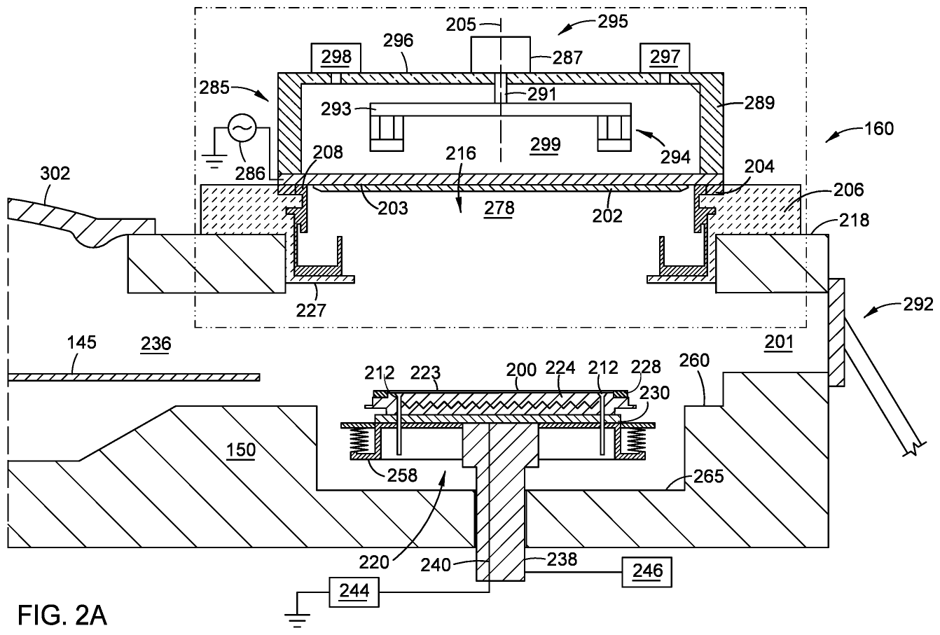

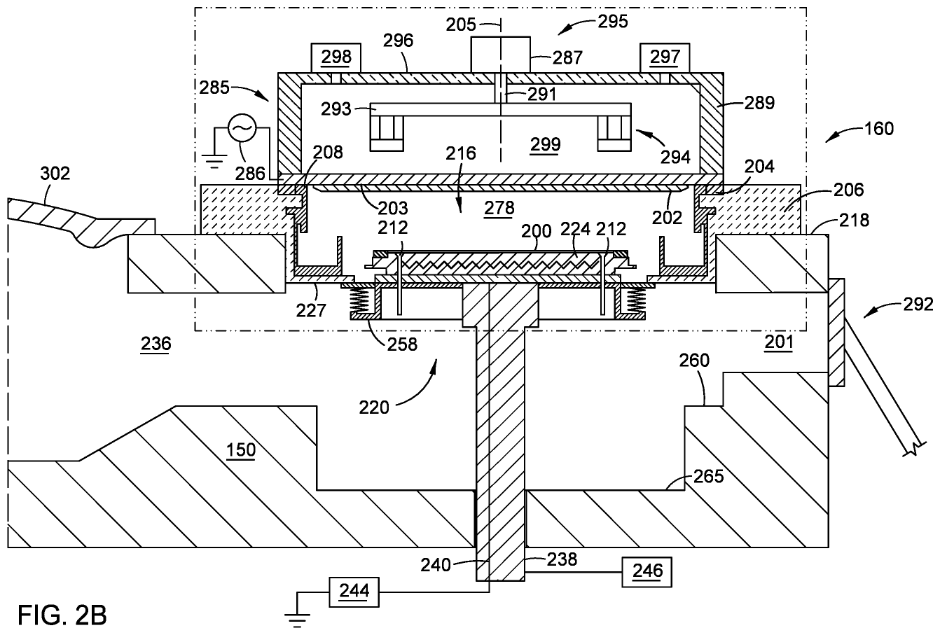

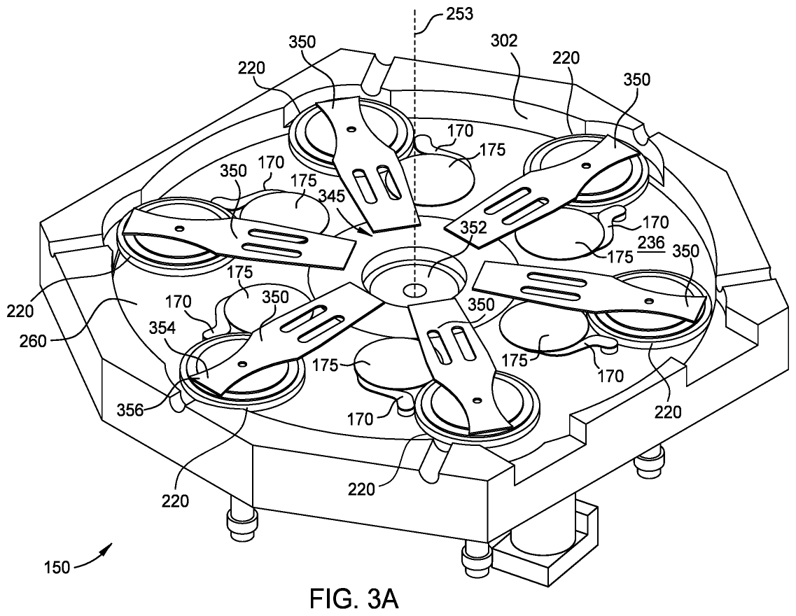

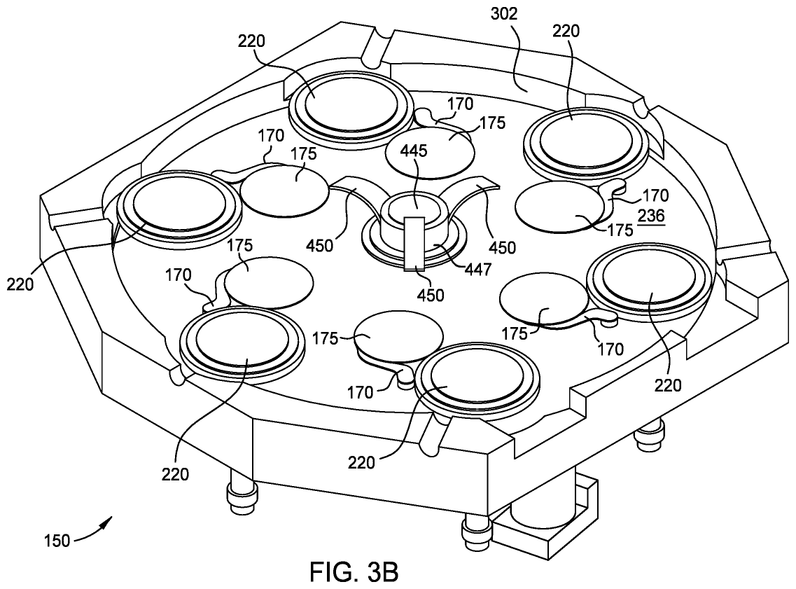

In certain embodiments, the substrate handling device 145 is disposed centrally within a transfer volume 236 (FIGS. 2A-2B) formed within the processing module 150, such that a central axis 155 of the processing module 150 is disposed through the substrate handling device 145. The substrate handling device 145 may be any suitable handling device configured to transport substrates between each of the processing stations 160. In one embodiment, the substrate handling device 145 is a central transfer robot having one or more moveable arms configured to selectively move a substrate between the processing stations 160. In another embodiment, the substrate handling device 145 is a carousel system by which substrates are moved along a circular orbital path centered on the central axis 155 of the processing module 150. In another embodiment, the substrate handling device 145 is an indexer arm system by which a plurality of arms may grab a substrate and move the substrate between the processing stations 160. The embodiments of the substrate handling device 145 of the present disclosure is further described herein and illustrated in FIGS. 3A-B and 5A-B.

Each processing module 150 includes a plurality of shutter disk assemblies 170 disposed therewithin. The plurality of shutter disk assemblies 170 may be positioned radially outward from the substrate handling device 145 within the transfer volume 236 of the processing module 150. Each shutter disk assembly 170 holds a shutter disk 175 (FIGS. 3A and 3B) and is configured to move the shutter disk 175 to a position below a corresponding processing station 160 within the processing module 150. FIG. 1A depicts an embodiment having six shutter disk assemblies 170 within the processing module 150. However, other embodiments may have a different number of shutter disk assemblies 170 within the processing module 150. In one embodiment, the processing module includes a shutter disk assembly 170 for each of the processing stations 160. A more detailed description of an exemplary shutter disk assembly 170 and shutter disk 175 is provided below.

FIG. 1B is a plan view of the cluster tool 100b with multiple processing modules 150 connected thereto. The FOUPs 110, FI 120, and load lock chambers 130 may be arranged similarly to the FOUPs 110, FI 120, and load lock chambers 130 described above in related to FIG. 1A. The cluster tool 100b of FIG. 1B further includes an FI etch apparatus 115, a buffer chamber 140, and a plurality of processing modules 150.

The buffer chamber 140 is located between the load lock chambers 130 and the plurality of processing modules 150 and provides an isolatable volume through which substrates may be transferred among and between the load lock chambers 130 and the multiple processing modules 150. The buffer chamber 140 is coupled to both the load lock chambers 130 and the plurality of processing modules 150. As shown in FIG. 1B, three processing modules 150 are disposed around and attached to the buffer chamber 140. In other embodiments, one, two, or more than three processing modules 150 may be disposed around the buffer chamber 140. The buffer chamber 140 may include at least one opening 146 along each wall of the buffer chamber 140 that is in contact with a processing module 150 or a load lock chamber 130. Each of the openings 146 is sized to allow the passage of a substrate, a substrate chuck, a substrate on a substrate chuck, or a shutter disk to and from the processing modules 150. In some embodiments, there are two openings 146 along each wall of the buffer chamber 140 that is adjacent to the processing modules 150. This allows for the passage of two substrates to the processing module 150 from the buffer chamber 140 or from the processing modules 150 to the buffer chamber 140 simultaneously.

The buffer chamber 140 may include one or more buffer chamber transfer robots 148. The buffer chamber transfer robot 148 moves substrates, chucks, both substrates and chucks, or shutter disks between the processing module 150 and the load lock chambers 130. The buffer chamber transfer robot 148 may be any suitable substrate transfer robot. The buffer chamber 140 may be sealed from the process gases used in the processing stations 160 of the processing module 150 by a fluid isolation valve, such as a slit valve (not shown).

The processing modules 150 may be configured the same as the processing module 150 described above in FIG. 1A. This includes the placement and structure of the substrate handling device 145, the array of processing stations 160, the plurality of shutter disk assemblies 170 and the chamber pumps 165 within each of the processing modules 150. However, alternative embodiments of the processing modules 150 may be utilized.

Both cluster tool assemblies 100a, 100b illustrated in FIGS. 1A and 1B may further include a system controller 199. The system controller 199 controls activities and operating parameters of the automated components found in the processing system 100. In general, the bulk of the movement of a substrate through the processing system is performed using the various automated devices disclosed herein by use of commands sent by the system controller 199. The system controller 199 is a general use computer that is used to control one or more components found in the cluster tool assemblies 100a, 100b. The system controller 199 is generally designed to facilitate the control and automation of one or more of the processing sequences disclosed herein and typically includes a central processing unit (CPU) (not shown), memory (not shown), and support circuits (or I/O) (not shown). Software instructions and data can be coded and stored within the memory (e.g., non-transitory computer readable medium) for instructing the CPU. A program (or computer instructions) readable by the processing unit within the system controller determines which tasks are performable in the cluster tool assemblies. For example, the non-transitory computer readable medium includes a program which when executed by the processing unit is configured to perform one or more of the methods described herein. Preferably, the program includes code to perform tasks relating to monitoring, execution and control of the movement, support, and/or positioning of a substrate along with the various process recipe tasks and various processing module process recipe steps being performed.

FIGS. 2A-2B are schematic cross sectional views of a portion of the processing module 150 and one of the processing stations 160 according to one embodiment. The processing module 150 includes the substrate handling device 145 to transfer a substrate 200 onto a substrate support device 223 of a chuck 224 below the processing station 160. The support chuck 224 is attached to a lift assembly 220 positioned below the processing station 160. The processing station 160 further includes a magnetron assembly 295 and a processing region 216.

FIG. 2A depicts the processing module 150 when a substrate lift assembly 220 is in a lowered position. In the lowered position, the lift assembly 220 is positioned to receive a substrate processing component, such as the substrate 200 itself or a shutter disk 175. FIG. 2B depicts the processing module 150 while the lift assembly 220 is in a raised position. In the raised position, the substrate processing component, such as the substrate 200 or a shutter disk 175 is positioned within processing region 216 of the processing station 160. In some embodiments, the support chuck 224 remains attached to the lift assembly 220 while the substrate 200 is transported between the processing stations 160 within the processing module 150, and while the substrate 200 is processed within the processing region 216 of the processing station.

As illustrated in FIGS. 2A-2B, each of the processing stations 160 of the processing module 150 is positioned over a transfer volume 236 formed within the processing module 150. The transfer volume 236 is defined by a bottom chamber wall 260 and a sidewall 302 (FIGS. 3A-3B) of the processing module 150. The lift assembly 220 may be positioned in a recess 265 of the bottom chamber wall 260. An opening 201 and a plate and seal assembly 292 are disposed adjacent to the transfer volume 236 and processing station 160. The opening 201 is formed on the sidewall 302 of the processing module 150. The opening 201 is sized to allow a substrate processing component, such as the substrate 200 or a shutter disk 175, to pass therethrough. In certain embodiments, the front end transfer robot 185 (FIG. 1A) may carry or pass the substrate processing component through the opening 201. In another embodiment, the buffer chamber transfer robot 148 of the buffer chamber 140 (FIG. 1B) may carry or pass the substrate processing component through the opening 201. The opening 201 is sealed from the front end robot chamber 180 and/or the buffer chamber 140 between the movement of the substrate processing components to and from the processing module 150. The opening 201 is sealed using the plate and seal assembly 292 disposed on the outside of the opening 201.

In certain embodiments, the processing region 216 of each processing station 160 is a physical vapor deposition (PVD) process chamber, wherein a material to form a layer on a substrate 200 exposed therein is sputtered from a sputtering target assembly 203. Thus, the processing region 216 herein includes the sputtering target assembly 203, a dielectric isolator 204, a liner 206, a containment member 208, the magnetron assembly 295, and a lid member 296. Contained within the processing region 216 is a chamber volume 278.

The sputtering target assembly 203 is disposed on top of, and forms the enclosing cover of, the chamber volume 278. The sputtering target assembly 203 is circular as viewed from above and has a flat, i.e., generally planar top surface. An annular surface of the sputtering target assembly 203 is disposed on the dielectric isolator 204, which is a dielectric material having sufficient dielectric strength and size to electrically isolate the sputtering target assembly from the liner 206. The sputtering target assembly 203 is connected to and powered by an AC power source 286, such that the sputtering target assembly 203 is biased during substrate processing.

The sputtering target assembly 203 is disposed between the chamber volume 278 and a magnetron volume 299, defined by magnetron support walls 289 and the lid member 296. An edge of a sputtering target 202 within the sputtering target assembly 203 is located inwardly of the containment member 208 and the dielectric isolator 204. The sputtering target 202 is composed of the material to be deposited on a surface of the substrate 200 during sputtering. The sputtering target 202 may be a copper sputtering target for depositing as a seed layer in high aspect ratio features formed in the substrate 200. The sputtering target 202 may also include other materials, such as a copper-doped aluminum sputtering target. Alternatively, the sputtering target 202 is composed of a liner/barrier material used to line the surfaces of a trench, via or contact opening in a dielectric layer, and the material deposited on the surfaces of a trench, via, or contact opening is composed of the target material, and in some cases a compound formed of the target material. For example, a tantalum layer with an overlying tantalum nitride layer thereon can be formed on the surfaces of a trench, via, or contact opening by first sputtering the target in an inert gas environment, and then adding nitrogen into the process volume. Alternatively, a first metal of a first target material is sputtered onto the substrate 200 including the surfaces of a trench, via, or contact opening thereon. The substrate 200 is moved to a second chamber having the same or different target composition, and a reactant such as nitrogen is introduced into the process volume to form the compound layer over the non-compound layer.

The magnetron assembly 295 is disposed over the sputtering target assembly 203. The magnetron assembly 295 includes a plurality of magnets 294 supported by a base plate 293 connected to a shaft 291, which is axially aligned with the central axis 205 of the processing station 160. The shaft 291 is connected to a motor 287 disposed on the opposite side of the lid member 296 of the magnetron assembly 295. The motor 287 spins the shaft 291 so that the magnets 294 rotate within the magnetron volume 299. The magnetron volume 299 is defined by the lid member 296, the magnetron support walls 289 and the sputtering target assembly 203. In one implementation, the magnets produce a magnetic field within the processing region 216 near the front face of the sputtering target assembly 203 to maintain a plasma generated therein, such that a significant flux of ionized gas atoms strike the sputtering target assembly 203, causing sputter emissions of target materials. The magnets are rotated about the central axis 205 of the processing region 216 to increase uniformity of the magnetic fields across the surface of the sputtering target assembly 203. Fluid may be supplied through the magnetron volume 299 via a fluid supply 297 to control the temperature of the magnets 294 and the sputtering target assembly 203. The fluid may be deionized (DI) water or other suitable cooling fluids. The fluid may be removed from the magnetron volume 299 by a fluid evacuator 298.

As illustrated in FIGS. 2A-2B, the lift assembly 220 includes a support chuck 224, an upper lift section 230, and a seal ring assembly 250. The support chuck 224 and lift assembly 220, collectively, include an edge ring 228, a support element 238, the upper lift section 230, an electrical line 240, and the seal ring assembly 250. The lift assembly 220 may further include a plurality of lift pins 212 disposed therethrough for raising or lowering a substrate 200 or a shutter disk 175 from a substrate support surface 223.

The support chuck 224 supports the substrate 200 and the edge ring 228. In certain embodiments, the support chuck 224 is an electrostatic chuck, such that the support chuck 224 can be biased by an electrical power source, such as the power source 244. The biasing of the support chuck 224 chucks the substrate 200 and holds the substrate 200 in place on the support chuck 224 during processing and movement of the lift assembly 220. The support chuck 224 may also contain heating elements (not shown) and thermal sensors (not shown). The heating elements and temperature sensors may also be connected to the power source 244 and assist in maintaining a uniform and controlled temperature across the supporting surface 223 and substrate disposed thereon. In other contemplated embodiments, the support chuck 224 may hold a shutter disk 175 from a shutter disk assembly 170. The support chuck 224 has a planar upper surface that forms the substrate supporting surface 223.

The lift assembly 220 includes an actuator 246, which is coupled to one or more motors. A controller (not shown), such as the controller 199, may be coupled to the lift assembly 220 via the actuator 246. The actuator enables vertical and rotational movement of the support chuck 224, such that the support chuck 224 can move vertically upwards and downwards through the transfer volume 236 and rotationally about the central axis 205.

The support chuck 224 is disposed on top of the lift assembly 220, such that the support chuck 224 is disposed on top of the upper lift section 230. In some embodiments, the support chuck 224 may detach from the lift assembly 220 while the support chuck 224 is transported between processing stations 160.

As the lift assembly 220 moves toward the bottom chamber wall 260, a processing region 216 of the lift pin 212 extends above the substrate support surface 223. When engaging a substrate processing component, such as the substrate 200 or a shutter disk 175, the lift pin 212 extends above the substrate supporting surface 223, so that the substrate handling device 145 can engage with the substrate processing component. As the lift assembly 200 moves toward the sputtering target 203, the top 216 of the lift pin 212 can retreat beneath the substrate support surface 223, allowing the substrate 200 or the shutter disk 175 to rest upon the substrate support surface 223. The seal ring assembly 250 is disposed and in contact with the upper lift section 230 of the support chuck 224. The seal ring assembly 250 extends radially outward from the central axis 205. The seal ring may further include a biasing member 258 to assist in sealing the chamber volume 278, as shown in FIG. 2B.

FIG. 2B includes the same components as FIG. 2A. FIG. 2B illustrates the processing station 160 when the lift assembly 220, including the support chuck 224, and the seal ring assembly 250, is in an upper position or the processing position. The lift assembly 220 is configured to move away from the bottom chamber wall 260 to the processing position shown. Accordingly, when the lift assembly 200 moves upwards into the processing position, the seal ring assembly engages with a ringed portion 227 of the processing station 160 to seal the chamber volume 278 of the processing region 216 from the transfer volume 236. With the processing region 216 sealed, a process is performed on a substrate 200 within the chamber volume 278. In some embodiments, a shutter disk 175 may be moved by the lift assembly 220 into the processing region 216. Accordingly, a process, such as a pasting or burn-in process, may be performed in the sealed chamber volume 278.

FIGS. 3A and 3B each illustrate a partial isometric top view of the processing module 150, according to different embodiments. In FIGS. 3A-3B, the transfer volume 236 is defined by the bottom chamber wall 260 and a circular sidewall 302. In the illustrated embodiments, the processing module 150 includes a substrate handling device 145 centrally positioned within the transfer volume 236. FIG. 3A depicts a processing module 150 including an indexer arm assembly 345 as the substrate handling device 145.

The indexer arm assembly 345 includes a plurality of support arms 350 disposed on a central support 352. The plurality of support arms 350 may be affixed to the central support 352 by a plurality of mechanical fasteners, such as threaded fasteners (not shown). The central support 352 may be rotated by a motor (not shown) disposed beneath or within the processing module 150 by a drive shaft or other rotational device. The motor may rotate the indexer arm assembly 345 about a central axis 253 to move one or more substrates 200 within the transfer volume 236.

Each of the plurality of support arms 350 is shaped and sized to support a substrate 200. For example, in some embodiments, each support arm 350 of the indexer arm assembly 345 may include a substrate support 354 disposed at an outer end 356 of each support arm 350. The substrate support 354 may be of any suitable shape as to hold and support a substrate 200. In some embodiments, the number of support arms 350 coupled to the central support 352 equals the number of processing stations 160 and/or lift assemblies 220 of the processing module 150. However, in some embodiments, the number of support arms 350 coupled to the central support 352 may be more or less than the total number of processing stations 160 and/or lift assemblies 220. During operation of the processing module 150, the plurality of support arms 350 are simultaneously rotated by the central support 350, so as to move a plurality of substrates 200 within the transfer volume 236. A more detailed description of the operation of the indexer arm assembly 345 is provided herein below.

The processing module 150 includes a plurality of shutter disk assemblies 170 and lift assemblies 220 disposed within the transfer volume 236. The shutter disk assemblies 170 and lift assemblies 220 may be circumferentially positioned around the indexer arm assembly 345 within the transfer volume 236. Each shutter disk assembly 170 is positioned between two lift assemblies 220 and provides a shutter disk 175 to a lift assembly 220 to be transported into a processing station 160 for a burn-in or pasting process during the substrate processing sequence

FIG. 3B depicts the processing module 150 having a central transfer robot 445 as the substrate handling device 145. The processing module 150 of FIG. 3B may have similar components as the processing module 150 of FIG. 3A. For example, the processing module 150 includes a plurality of shutter disk assemblies 170 and lift assemblies 220 disposed within the transfer volume 236. The shutter disk assemblies 170 and lift assemblies 220 may be circumferentially positioned around the central transfer robot 445 within the transfer volume 236. Each shutter disk assembly 170 is positioned between two lift assemblies 220 and provides a shutter disk 175 to a lift assembly 220 to be transported into a processing station 160 for a burn-in or pasting process during the substrate processing sequence.

Similar to the indexer arm assembly 345 of FIG. 3A, the central transfer robot 445 of FIG. 3B is disposed centrally within the transfer volume 236 of the processing module and moves the substrate 200 within the transfer volume 236 during the substrate processing sequence. The central transfer robot 445 includes a plurality of support arms 450 coupled to a central support 452. The support arms 450 may be frog-like robot arms which extend between a normal position and an extended position (not shown). Generally, the number of support arms 450 of the central transfer robot 445 is less than the total number of processing stations 160 of the processing module 150. However, in other certain embodiments, the central transfer robot 445 may have more or less support arms 450 than the total number of processing stations 160 of the processing module 150. The central transfer robot 445 further includes an actuator 447 coupled to the central support 452. In some embodiments, the actuator 447 is in communication with a controller, such as the controller 199 (FIG. 1A-1B). The controller 199 gives the actuator instructions to move the central support 452 and support arms 450 within the transfer volume 236.

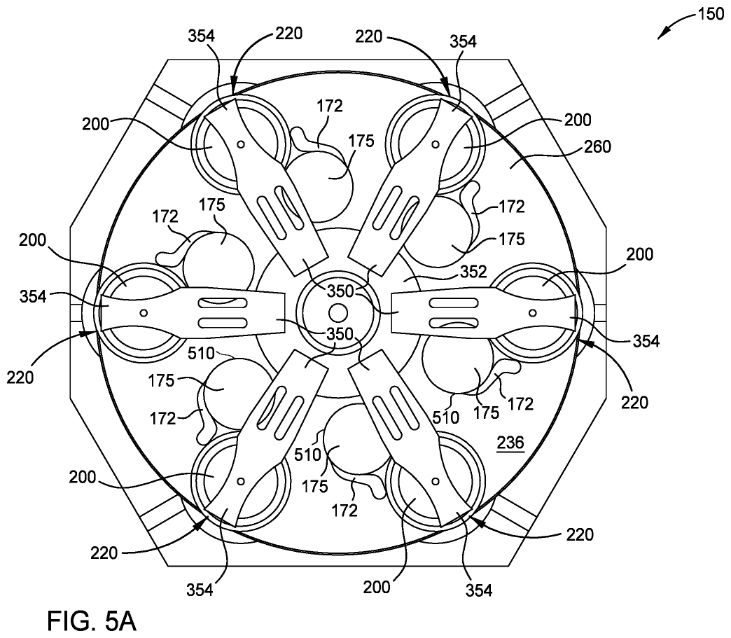

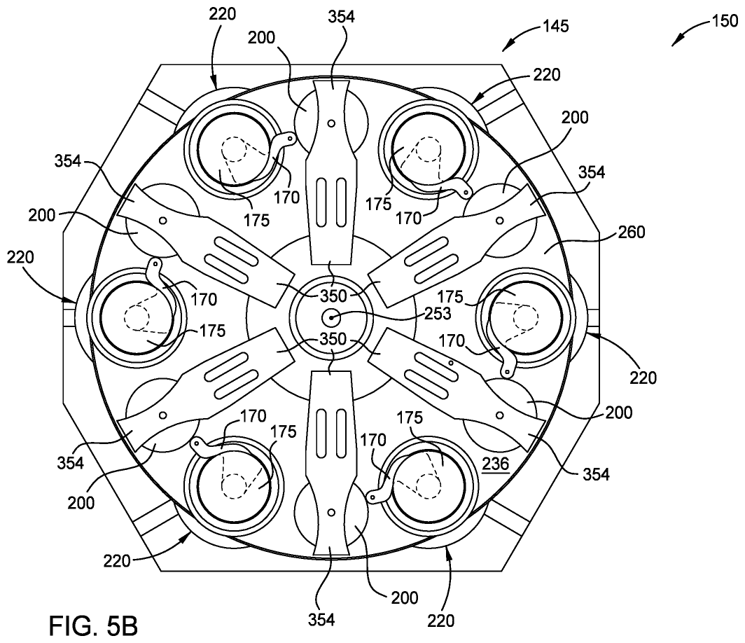

Accordingly, each support arm 450 of the central transfer robot 445 may selectively grab a substrate 200 from the substrate support surface 223 of the lift assembly 220 and move the substrate within the transfer volume 236 to either another lift assembly 220 or a second position within the transfer volume 236 while a burn-in or pasting process is performed within a processing station 160. As further described herein, the shutter disk assembly 170 may rotate a shutter disk 175 from a home position (FIG. 5A) to a position over one of the lift assemblies 220 once the central transfer robot 445 removes a substrate from the substrate support surface 223. In the home position, the shutter disk blade 172 and shutter disk 175 are stored in the shutter disk storage area 510 (FIG. 5A). The lift assembly 220 may raise shutter disk 175 disposed on the substrate support surface 223 and the chuck 224 into the processing station 160 to perform a burn-in or pasting process.

Both the indexer arm assembly 345 and the central transfer robot 445 allow for the system to selectively move multiple substrates 200 within the processing module 150 and between processing stations 160. As such, the indexer arm assembly 345 or the central transfer robot 445 may simultaneously move a plurality of substrates 200 within the processing module 150. In other embodiments, the indexer arm assembly 345 or the central transfer robot 445 moves only a portion of the substrates 200 being processed within the processing module 150. For example, the indexer arm assembly 345 or the central transfer robot 445 may remove one or two substrates 200 from a lift assembly 220 after a processing sequence has occurred in the corresponding processing stations 160. In this embodiment, the one or two substrates 200 are removed from the lift assembly 220 and moved to a second position within the transfer volume 236 by the indexer arm assembly 345 or the central transfer robot 445. Accordingly, while the one or two substrates 200 are in the second position, one or more substrates 200 may remain within a corresponding processing station 160 until the completion of a processing sequence. The selective control of the substrate handling device 145, i.e., the indexer arm assembly 345 or the central transfer robot 445, allows for individual processing sequences to occur on different substrates 200 within each processing station 160 of the processing module 150. Accordingly, the plurality of shutter disk assemblies 170 disposed within the transfer volume 236 allows for selective burn-in or pasting processes to occur once a substrate 200 has been removed from the lift assembly 220 beneath a processing station 160 by the substrate handling device 145.

In other embodiments, the substrate handling device 145 may be a carousel type robot assembly (not shown). The carousel type robot assembly has similar components to the indexer arm assembly 345. For example, the carousel type robot assembly may have a plurality of support arms 350 coupled to a central support 352 configured to rotate about a central axis 253. Each of the plurality of support arms 350 is configured to move at least one substrate within the transfer volume 236. The carousel type robot assembly further includes a moveable substrate support (not shown) disposed on each end of the plurality of support arms 350. Accordingly, the carousel type robot assembly moves both the substrate support and the substrate within the transfer volume 236 between each of the plurality of processing stations 160.

FIGS. 3A-3B further illustrate a plurality of lift assemblies 220 disposed within the transfer volume 236. Each of the plurality of lift assemblies 220 may be circumferentially arrayed within the transfer volume 236 and positioned below each of the processing stations 160 of the processing module 150. Each lift assembly 220 may be disposed within a recess 265 formed in the bottom chamber wall 260 within the transfer volume 236 of the processing module 150. As previously discussed, the lift assemblies 220 move a substrate processing component, such as a substrate 200 or a shutter disk 175, from the transfer volume 236 into one of the processing stations 160. The lift assemblies 220 include a plurality of lift pins 212 extending through the substrate support surface 223 to remove the substrate 200 or shutter disk 175 from either the substrate handling device 145 or a shutter blade 172. Once the lift assembly 220 has moved the substrate 200 or the shutter disk 175 into the processing station 160, a substrate processing sequence is performed. Accordingly, once the substrate processing sequence is performed, such as a PVD process or a pasting or burn-in process, the lift assembly 220 lowers the substrate 200 or the shutter disk 175 from the processing station 160 back to the transfer volume 236.

FIGS. 3A-3B further illustrate a plurality of shutter disk assemblies 170 disposed proximate to the each of the lift assemblies 220 within the transfer volume 236. Each shutter disk assembly 170 may be positioned between a lift assembly 220 in the bottom chamber wall 260 as to correspond to a single processing station 160 disposed over one of the lift assemblies 220. FIGS. 3A-3B illustrate a processing module 150 having six shutter disk assemblies 170 corresponding to six lift assemblies 220. However, the present disclosure is not so limited. For example, the processing module may contain between two and twelve shutter disk assemblies 170 and/or lift assemblies 220 disposed within the processing module 150. In some embodiments, the number of processing stations 160, lift assemblies 220 and shutter disk assemblies 170 are all equal. In yet another embodiment, there may be a different number of processing stations 160, lift assemblies 220, and/or shutter disk assemblies 170 within the processing module 150. Accordingly, each of the processing stations 160 may be configured to perform the same processing sequence. For example, in the current embodiment, each of the processing stations 160 is configured to perform a PVD process on the substrate 200 positioned therewith in.

A shutter disk assembly 170 can provide a shutter disk 175 to a processing station 160. The shutter disks 175 can be utilized for preconditioning the process stations 160 either during an initial burn of the chambers that make up the process station 160, or the shutter disks 175 can be for target or process kit cleaning. The shutter disks 175 can also be used for a pasting process within the process station 160. The pasting process is an in situ conditioning process step that uses existing materials (targets or gas) or adds new materials (e.g., gas) to create a blank cover film over all of the process environment surfaces in the process station 160, in order to reduce defects or other lifetime driven performance effects. The shutter disks 175 are used to protect surfaces that otherwise would normally not be exposed to the process within the processing station 160 and thereby allow for the cleaning the target 202 within the substrate target assembly 203.

Each shutter disk assembly 170 supports a shutter disk 175 during operation of the processing module 150 and eliminates the need to break the vacuum within the processing module 150 when a burn-in or pasting process is required for one of the process stations 260. Additionally, by disposing the shutter disk assemblies 170 within the transfer volume 236 outside of the processing stations 160, each shutter disk 175 is transported into the processing station 160 without breaking vacuum of the processing module 150. Reducing the need to break vacuum decreases processing time of the processing module 150, and ultimately reduces costs to the user.

The plurality of shutter disks 175 positioned on the shutter disk assemblies 170 are configured to protect underlying components from unwanted deposition. Each shutter disk 175 can have a diameter of about 300 mm or larger. The larger diameter of the shutter disks allows for protection of the underlying components even if the structure of the shutter disk 175 is affected by a substrate processing sequence within the processing station 160. For example, the shutter disk 175 may be of such diameter as to cover the support chuck 224 and/or substrate support surface 223 when a burn-in or pasting process is performed within one of the processing stations 160.

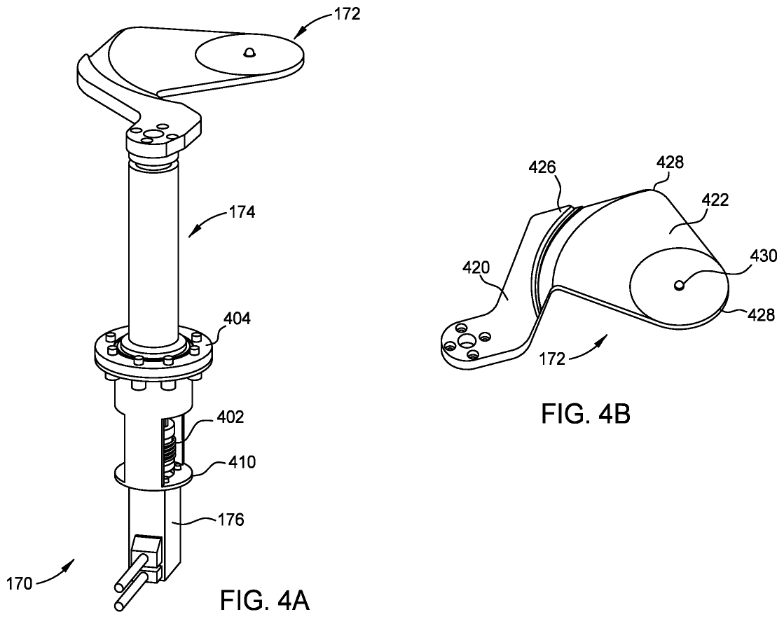

FIG. 4A illustrates an isometric view of a shutter disk assembly 170, according to some embodiments. The shutter disk assembly 170 includes a shutter disk blade 172 coupled to a shaft 174 which may be rotated by an actuator 176. The actuator 176 may be any type of motor configured to provide rotational power to the shaft 174, such as an electric motor, hydraulic motor, or pneumatic motor. The actuator 176 may be connected to a central control system (not shown), such as controller 199, which may individually and/or selectively operate each shutter disk assembly 170 of the processing module 150. Accordingly, the actuator 176 rotates the shaft 174 to pivot the shutter disk blade 172 between a home position (FIG. 5A) and a shuttering position (FIG. 5B) within the transfer volume 236 of the processing module 150. The shutter disk assembly 170 further includes a rotary coupler 402 coupled to both the actuator 176 and the shaft 174. The rotary coupler 402 facilitates the rotational movement between the actuator 176 and the shaft 174.

The shutter disk assembly 170 further includes a feedthrough device 404 disposed around the shaft 174 above the rotary coupler 402. The feedthrough device 404 allows for the rotational movement supplied by the actuator 176 to be provided from the ambient or atmospheric pressure side of the processing module 150 to the vacuum within the processing module 150. In some embodiments, the feedthrough device 404 is a ferrofluid feedthrough device which utilizes a magnetic fluid, magnets, and a magnetically permeable shaft to produce a series of liquid O-ring-like seals around the magnetically permeable shaft and create a hermetic seal. Accordingly, the feedthrough device provides a seal for the vacuum within the processing module 150 while still allowing for the translation of rotational movement between the actuator 178 to the shutter disk blade 172. The shutter disk assembly 170 further includes an adapter 410 coupled to the feedthrough device 404 and disposed around the shaft 174. The adapter 410 provides additional structural support between the feedthrough device 404 and the actuator 178.

In another embodiment not illustrated, the shaft 174 may include an extension shaft coupled to a main shaft by a rigid coupling device as to allow the extension shaft and the main shaft to rotate together when a rotational movement is provided by the actuator 178. Accordingly, the shutter disk blade 172 is coupled to the extension shaft, and the main shaft is coupled to the actuator 178 by the rotary coupler 402 and extends through the feedthrough device 404.

Accordingly, each of the plurality of shutter disk assemblies 170 extends through the bottom chamber wall 260 of the processing module 150 and is positioned proximate to the plurality of lift assemblies 220 within the transfer volume 236. In certain embodiments, there are an equal number of shutter disk assemblies 170 and lift assemblies 220 within the transfer volume 236. Each of the plurality of lift assemblies 220 is positioned beneath a processing station 160 configured to perform a substrate processing sequence. In some embodiments, the shutter disk blade 172 may be positioned in a shutter disk storage area 510. The shutter disk storage area is proximate to the lift assembly 220 within the transfer volume 236. In some embodiments, the shutter disk storage area 510 may include a shutter disk garage (not shown). The shutter disk garage may be of such shape as encompass a substantial amount of the shutter disk blade 172 and shutter disk 175 when the shutter disk assembly is positioned therewithin. Accordingly, the shutter disk garage provides additional protection for the shutter disk 175 and shutter disk blade 172 within the transfer volume 236.

FIG. 4B illustrates a top isometric view of the shutter disk blade 172 of the shutter disk assembly 170, according to certain embodiments. The shutter disk blade 172 includes an arm portion 420 and a body portion 422 for holding and rotating the shutter disk 175. The arm portion 420 is coupled to the shaft 174 of the shutter disk assembly 170. In some embodiments, the body portion 422 of the shutter disk blade 172 includes a rounded edge 426. The rounded edge 506 may be of a certain height as to provide lateral support to a shutter disk 175 during movement of the shutter disk 175 and shutter disk assembly 170. The body portion 422 of the shutter disk blade 172 may be generally triangular in shape and have curved edges 428. The body portion 422 may further include a notch 430 disposed centrally for engaging with the bottom surface (not shown) of the shutter disk 175. In other embodiments not presently shown, the shutter disk blade 175 may include a series of circular openings (not shown) for reducing the overall weight of the shutter disk blade 172.

FIGS. 5A-5B illustrate a partial top view of the processing module 150 according to certain embodiments. In the illustrated embodiments, the processing module 150 includes similar components as those described above in relation to FIGS. 1A-1B, 2A-2B and FIGS. 3A-3B such as: a plurality of shutter disk assemblies 170, a substrate handling device 145, a plurality of lift assemblies 220, a transfer volume 236 formed within the processing module 150, and an array of processing stations 160 (removed in FIGS. 5A-5B for clarity) disposed over the transfer volume 236. The shutter disk assemblies 170 and the lift pin assemblies 220 are arrayed, and are equally and circumferentially spaced from one another, in a similar arrangement as the processing stations 160. Accordingly, in certain embodiments, one shutter disk assembly 170 is positioned proximate to each lift assembly 220 within the processing module 150. While the embodiment illustrated in FIG. 5A depicts a processing module 150 with six shutter disk assemblies 170 (corresponding to six processing stations 160 positioned thereover but not shown) and six lift assemblies 220, the processing module 150 may have between two and twelve processing stations 160 and two to twelve corresponding shutter disk assemblies 170 and/or lift assemblies 220 disposed therewithin.

As mentioned, the plurality of shutter disk assemblies 170 disposed within the transfer volume 236 allows for selective burn-in or pasting processes to occur once a substrate 200 has been removed from the lift assembly 220 beneath a processing station 160 by the substrate handling device 145. FIGS. 5A-5B illustrate a top view of the processing module 150 with an indexer arm assembly 345 disposed within the transfer volume 236. The indexer arm assembly 345 includes the same components as previously discussed in relation to FIG. 3A, and is configured to move one or more substrates 200 within the processing module 150.

Accordingly, FIG. 5A depicts the indexer arm assembly 345 carrying a plurality of substrates 200 within the processing module 150. More specifically, the indexer arm assembly 345 carries a plurality of substrates 200 within the transfer volume 236 between a plurality of processing positions beneath a processing station 160. Once a substrate 200 is positioned beneath a processing station 160, the lift assembly 220 disposed in the bottom wall chamber 260 of the processing module may lift each of the substrates 200 from the substrate support 354 of the support arms 350. As discussed in relation certain embodiments illustrates in FIGS. 2A-2B, the lift assembly 220 includes a plurality of lift pins 212 which engage with the underside of a substrate 200 to lift the substrate from the substrate support 354 of each support arm 350. The entire lift assembly 220, including the chuck 224 and substrate support surface 223 may be raised to engage with the substrate 200 and continue to move upwards into the processing station 160 for a processing sequence. FIG. 5A illustrates a first position of the indexer arm assembly 345. In the first position, at least one substrate 200 may be positioned on a substrate support 354 and located beneath a processing station 160 as to allow for a processing sequence to occur.

FIG. 5A further illustrates the shutter disk assemblies 170 disposed within the transfer volume 236 formed by the bottom chamber wall 260 and the sidewall 302 of the processing module 150. Each shutter disk assembly is positioned proximate to a corresponding lift assembly 220 beneath each of the processing stations 160 within the array. A portion of each shutter disk assembly 170 may be disposed through the bottom chamber wall 260 of the processing module 150. Accordingly, only a portion of each shutter disk assembly 170 may be present within the transfer volume 236 of the processing module 150, such as a shutter disk blade 172 and a portion of a rotatable shaft 174. FIG. 5A depicts a processing module 150 with six shutter disk assemblies, and thus six shutter disk blades disposed therein. Accordingly, each of the shutter disk blades 172 are rotatable between a home position (FIG. 5A) and a shuttering position (FIG. 5B). The rotation of each shutter disk blade 172 allows for a different processing sequence to occur in each processing station 160 at different points in time, without regard to the processing sequences occurring in the other processing stations 160 of the processing module 150.

Accordingly, when the indexer arm assembly 345 carrying at least one substrate 200 is positioned in the first position illustrated in FIG. 5A, the plurality of lift assemblies 220 may lift the substrates 200 from the substrate supports 354 and move the substrates into the processing station 160 positioned thereabove for a processing sequence to occur. In exemplary embodiments, the processing sequence performed within the processing station 160 is a PVD process, as is described herein. After performing the substrate processing sequence(s) in the process station 160, the substrate 200 and substrate support surface 223 of the lift assembly 220 are lowered so that the substrates 200 are located on the support arm 350 of the indexer arm assembly 345. After the processing sequence(s) are performed, each processing station 160 within the array may require a burn-in or pasting process to occur. In some embodiments, only less than all of the processing stations 160 may require a burn-in or pasting process to occur. Accordingly, the indexer arm assembly 345 and plurality of shutter disk assemblies 170 of the present invention allow for the burn-in or pasting process to occur without the need to break the vacuum of the processing module as to allow for a shutter disk 175 to be brought into the transfer volume 236 from a position outside of the processing module.

Each shutter disk 175 protects the substrate support surface 223 and the chuck 224 of the lift assembly 220 during the burn-in or pasting process. Before the shutter disks 175 are provided to the lift assembly 220, the indexer arm assembly 345 rotates the central support 305 about the central axis 253 extending therethrough to swing the support arm 350, substrate 200 and substrate support 354 through an arc to index the substrate support 354 and substrate 200 to a second position between two of the lift assemblies 220. FIG. 5B illustrates the indexer arm assembly 345 in the second position. The second position of the indexer arm assembly 345 may be proximate to or over the shutter disk assembly 170 and shutter disk 175. However, the indexer arm assembly 345 holding the substrate 200 does not interfere with the rotation of the shutter disk blade 172 and shutter disk 175.

With the substrate 200 indexed in the second position, the actuator 178 (not shown) of the shutter disk assembly 170 may rotate the shaft 174 (not shown) to pivot the shutter disk blade 172 within the transfer volume 236 between a home position (FIG. 5A) and a shuttering position (FIG. 5B). In the shuttering position, the shutter disk blade 172 and the shutter disk 175 are positioned over a lift assembly 220 and beneath a corresponding processing station 160. After the shutter disk 175 is positioned over the lift assembly 220, the lift assembly 220 may raise the shutter disk 175 from the shutter disk blade 172. The lift assembly may use a plurality of lift pins 212 to lift the shutter disk 175 from the shutter disk blade 172. Accordingly, as the chuck 224 and substrate support surface 223 are raised by the lift assembly 220, the lift pins 212 may retract into the substrate support surface 223, allowing the shutter disk 175 to engage with substrate support surface 223. With the substrate support surface 223 covered by the shutter disk 175, the lift assembly 220 further lifts the chuck 224, substrate support surface 223, and shutter disk 175 into the processing station 160. Once the processing station 160 is sealed, a burn-in or pasting processing may occur within the process volume 216 (FIG. 2B).

After the burn-in or pasting process has occurred, the lift assembly 220 lowers the chuck 224, substrate support surface 223, and shutter disk 175 from the processing station 160. As the lift assembly 220 descends within the transfer volume 236, the plurality of lift pins 212 may reengage the bottom of the shutter disk 175 as to lift the shutter disk 175 from the substrate support surface 223. With the shutter disk 175 positioned on the lift pins 212, the shutter disk 175 may reengage with the shutter disk blade 172. Once the shutter disk 175 has been positioned on the shutter disk blade 172, the shutter disk blade 172 is pivoted from the shuttering position (FIG. 5B) back to the home position (FIG. 5A).

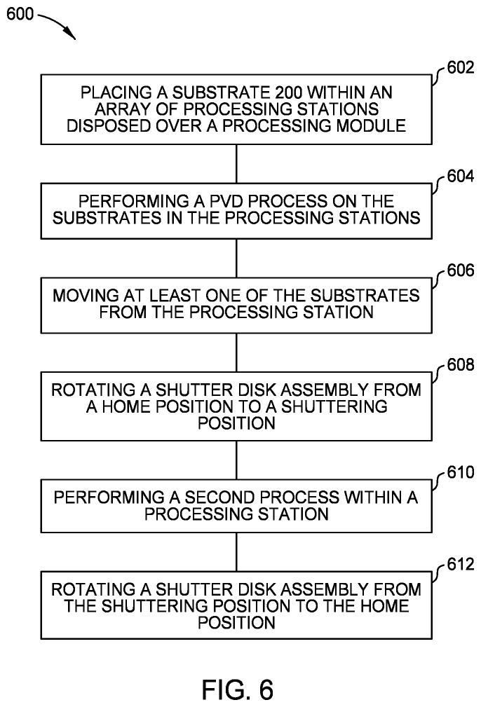

FIG. 6 depicts a flow chart of a method 600 of moving a plurality of shutter disks 175 within the processing module 150. The method 600 is enabled by the apparatus described in FIGS. 5A-5B with regard to the operation of the indexer arm assembly 345 and the shutter disk assembly 170. In some embodiments, the method 600 may include additional process operations other than those described herein.

The first operation 602 of the method 600 is placing at least one substrate 200 within an array of processing stations disposed within the processing module 150. In the first operation 602, the array of processing stations 160 are identical to those described in FIGS. 2A-2B. The plurality of substrates 200 may be placed within the array of processing stations 160 by the plurality of lift assemblies 220 disposed within the transfer volume 236 of the processing module 150. Prior to placing of the plurality of substrates 200, the substrate handling device 145 may move the substrates 200 between positions beneath each processing station 160, such that the substrates 200 are positioned over each lift assembly 220. In some embodiments, the substrate handling device 145 is the indexer arm assembly 345. In yet other embodiments, the substrate handling device 145 is the central transfer robot 445. Alternatively, any suitable transfer robot may be used to move the plurality of substrates 200 within the processing module. After the plurality of substrates 200 are positioned over the lift assemblies 220, the lift assemblies 220 lift the substrates from the substrate handling device 145 into the processing stations 160.

In the second operation 604 of the method 600, a PVD process is performed on the substrates 200 within the array of processing stations 160. The PVD process may form one or more layers of a material on each substrate 200. In certain embodiments, all of the substrates 200 placed within the processing module 150 are simultaneously positioned within the processing stations 160. For example, FIG. 5A-5B depict six substrates 200 being positioned within the processing stations 160. In other embodiments, only a select few substrates 200 may be positioned within a processing station 160. Accordingly, the remaining substrates 200 may be indexed or held within the transfer volume 236 by the substrate handling device 145.

In the third operation 606 of the method 600, at least one substrate 200 is moved from one of the processing stations 160. The lift assemblies 220 may lower the substrates 200 disposed on the substrate support surface 223 from the processing position within the processing stations 160 to a position proximate the substrate support 354 of the substrate handling device 145. In some embodiments, operation 606 may use a plurality of lift pins 212 disposed within each lift assembly 220 to facilitate the transfer of the substrates 200 between the lift assembly 220 and the substrate support 354 of the substrate handling device 145. Once the substrates 200 have been placed on the substrate handling device 145, the substrate handling device 145 may rotate as to index the substrates to a second position. In some embodiments, the second position at operation 606 may be above another lift assembly 220 within the processing module 150. Alternatively, the second position may be between two lift assemblies 220 within the transfer volume 236.

Operation 608 of the method 600 includes rotating a shutter disk assembly 170 from a home position to a shuttering position. The home position of the shutter disk assembly 170 is depicted in FIG. 5A. The shuttering position of the shutter disk assembly 170 is depicted in FIG. 5B. Accordingly, the rotating the shutter disk assembly 170 includes using the actuator 178 to rotate the shaft 174 to pivot the shutter disk blade 172 between the home position and the shuttering position. As mentioned, the shutter disk blade 172 holds a shutter disk 175. By pivoting the shutter disk blade 172 into the shuttering position, the shutter disk 175 is positioned over the lift assembly 220 and beneath the corresponding processing station 160. In certain embodiments, all of the substrates 200 may be simultaneously removed from the processing positions beneath each of the processing stations 160. In such embodiments, all of the shutter disk blades 172 and shutter disks 175 of the shutter disk assemblies 170 may be simultaneously moved between the home position and the shuttering position. Alternatively, only some of the shutter disk blades 172 and shutter disks 175 may be moved between the home position and the shuttering position. As such, each processing station 160 may require a different frequency of burn-in or pasting processes to occur. Therefore, some processing stations 160 may not require a shutter disk 175 to be supplied by the shutter disk assembly 170 in the same instance as other processing stations 160 of the processing module 150.

Operation 610 of the method 600 includes performing a second process within a processing station 160. For example, the second process may be a burn-in or pasting process. When the operation 610 includes a burn-in or pasting process, the shutter disk 175 protects the chuck 224 and substrate support surface 223 while the process is performed. As mentioned, in some embodiments, operation 610 occurs in all of the processing stations 160 of the processing module 150. In other embodiments, a second process is performed in less than all of the processing stations 160.

Operation 612 of the method 600 includes rotating a shutter disk assembly 170 from the shuttering position the home position. According to some embodiments, prior to operation 612, the shutter disk 175 is lowered by the lift assembly 220 from the processing station 160 to the shutter blade 172. After the shutter disk 175 has reengaged with the shutter disk blade 175, the shutter disk assembly 170 may pivot the shutter disk blade 172 from the shuttering position to the home position.

While the indexing process and movement of a single shutter disk blade 172 has been described herein, the foregoing description of the operation and method of the shutter disk assembly 170 and indexer arm assembly 345 may occur simultaneously between each processing station 160 within the illustrated processing module 150. For example, the current processing module 150 illustrated in FIGS. 5A-5B includes six processing stations 160, six shutter disk assemblies 170, six substrates 200, and six lift assemblies 220.

After a PVD processing is completed on each of the six substrates 200, the substrates 200 are then placed back onto the end of the support arm 350 of the substrate handling device 145 and transferred to a second position (FIG. 5B) between two processing stations 160. Accordingly, all six shutter disk assemblies 170 may rotate between the home position (FIG. 5A) and the shuttering position (FIG. 5B). Next, all six lift assemblies 220 may lift the six shutter disks 175 from the shutter disk blades 172 and move each into the processing stations 160 to perform a burn-in or pasting process. Accordingly, the shutter disks 175 are removed from the processing stations 160 and returned to the home position by the shutter disk assemblies 170. The substrate handling device 145 then moves the six substrates 200 to the next processing station 160 of the array and the process is repeated. In another embodiment, each substrate 200 may be returned to the processing station 160 where the first PVD process occurred. The processing cycle of raising the substrate 200, processing the substrates 200, lowering the substrates 200 and transferring the substrates 200, performing a burn-in or pasting process can then be repeated multiple times as the substrates 200 move about the array of the processing module 150.

Alternatively, the processing module 150 selectively processes different substrates 200 within the processing stations 160. For example, the substrate handling device 145 may position one or more substrates 200 beneath corresponding processing stations 160, whereby the lift assemblies 220 beneath the processing stations 160 lift the substrate into the processing station 160 to perform a PVD process. While the first two substrates 200 are processed, the remaining substrates 200 within the processing module 150 are indexed between two other processing stations 160, as to allow for the shutter disk assembly 170 to provide a shutter disk 175 to the shuttering position. As such, certain processing stations 160 may be performing a PVD process on a substrate 200 while other processing stations 160 perform a burn-in or pasting process with a shutter disk 175 in place.

This design and transfer sequence also provides additional advantages since each process station 160 can be separately and selectively isolated. Additionally, when a processing station 160 requires a burn-in or pasting process to occur, the plurality of substrates 200 need not be removed from the transfer volume 236 of the processing module 150. As such, the vacuum within the transfer volume 236 is not broken and the time to process a substrate 200 is reduced.

Further, in a processing module 150 having a plurality of shutter disk assemblies 170 disposed therein, it is important to constantly monitor the location of each shutter disk blade 172 and shutter disk 175 within the transfer volume 236. When the location of a shutter disk blade 172 and shutter disk 175 is known by the user during substrate processing sequences, the likelihood that a collision between a shutter disk assembly 170 and another assembly of the processing module decreases. Thus, the processing module 150 further includes a plurality of sensors 700 which are positioned to determine the location and/or position of the plurality of shutter disk blades 172 and shutter disks 175.

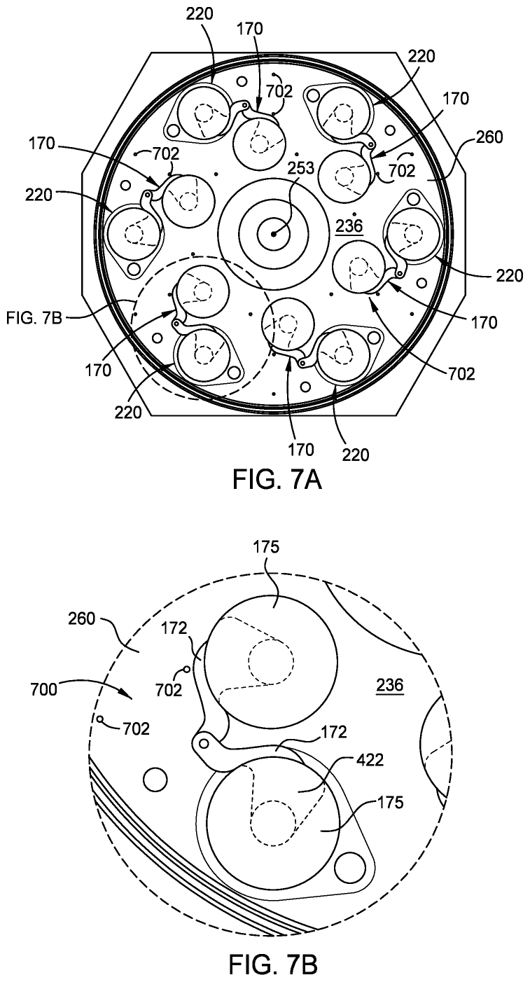

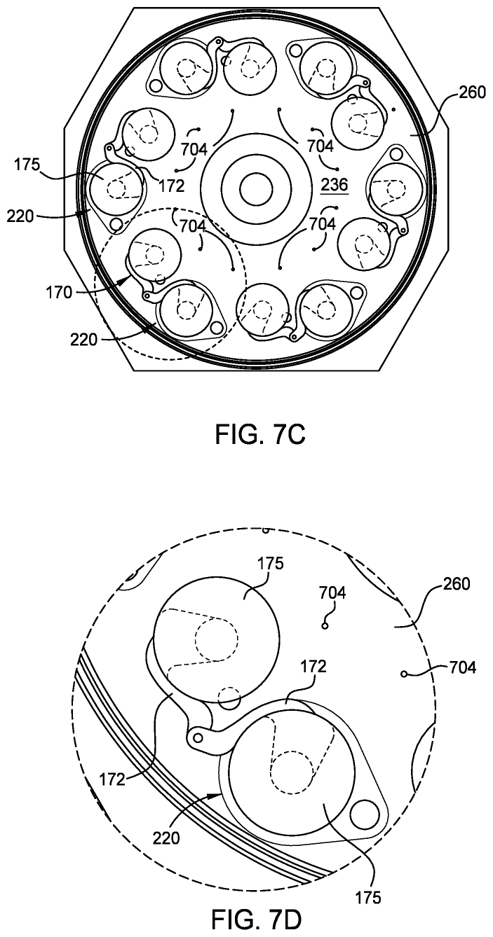

FIGS. 7A-7D depict partial top views of the processing module having a plurality of sensor assemblies 700 disposed therein, according to certain embodiments. Each sensor assembly 700 is disposed through the bottom chamber wall 260 of the processing module 150 and positioned proximate to a shutter disk assembly 170. In some embodiments, each sensor assembly 700 is an absolute encoder device configured to determine the absolute location of the shutter disk blade 172.

FIGS. 7A and 7B depict an embodiment of the processing module 150 including a plurality of outer sensors 702. The outer sensors 702 include pairs of two sensor assemblies 700 disposed proximate to each shutter disk assembly 170. FIGS. 7A and 7B illustrate that the outer sensors 702 are positioned radially outward from the substrate handling device 145 and the central axis 253 within the transfer volume 236. FIGS. 7C and 7D depict another embodiment of the processing module 150 having a plurality of inner sensors 704. The inner sensors 704 are disposed circumferentially around the area surrounding the substrate handling device 145 (not shown) within the transfer volume 236. In certain embodiments, the processing module 150 may include both the outer sensors 702 and the inner sensors 704 disposed within the bottom chamber wall 260 of the transfer volume 236.

By positioning the sensor assemblies 700 proximate to each of the shutter disk assemblies 170, the location of the shutter disk blade 172 and/or the shutter disk 175 is monitored during operations. As the shutter disk blade 172 is pivoted by the shutter disk assembly 170 between the home position (FIG. 5A) and the shuttering position (FIG. 5B), the sensor assemblies 700 detect the presence of the shutter disk blade 172. For example, when the shutter disk blade 172 is located in the home position, one or more outer sensors 702 may be disposed proximate to the shutter disk assembly 170 in the home position. In such embodiment, at least one outer sensor 702 is positioned below the shutter disk blade 172 in the home position. In some embodiments, both outer sensors 702 corresponding to a certain shutter disk assembly 170 may be positioned beneath the shutter disk blade 172. As such, when the shutter disk blade 172 is in the home position, the sensor 702 detects the presence of the blade 172.

When the shutter disk blade 172 is moved from the home position to the shuttering position, the outer sensors 702 are positioned to detect that the shutter disk blade 172 is no longer positioned in the home position. Accordingly, when the shutter disk blade 172 is moving from the home position to the shuttering position, the inner sensors 704 are positioned to detect the presence of the shutter disk blade 172 as it moves over each sensor assembly 700. By including both the outer sensors 702 and the inner sensors 704, the position of each shutter disk blade 172 of each shutter disk assembly 170 is more accurately determined. Thus, the potential for a collision between the shutter disk assemblies 170 and the other substrate processing components of the processing module 150 is reduced.

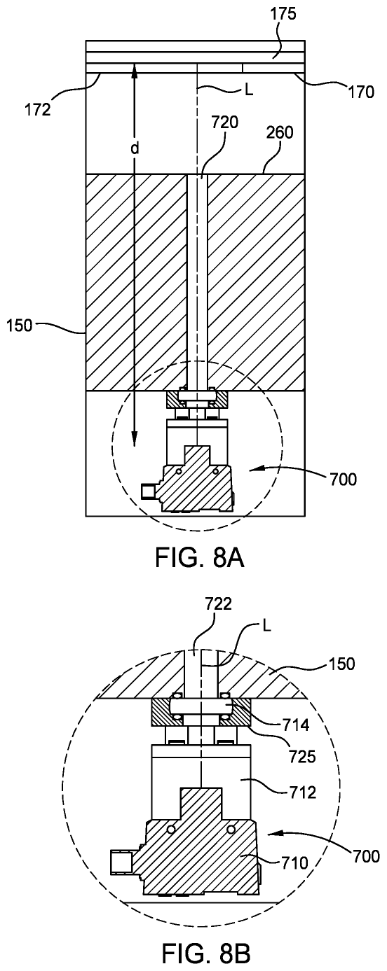

FIGS. 8A-8B depict a sensor assembly 700 disposed through the bottom chamber wall 260 of the processing module 150, according to certain embodiments. As illustrated, the sensor assembly 700 includes a laser sensor 710, a coupler 712 coupled to the laser sensor 710. The sensor assembly 700 further includes a quartz window 714 disposed below an opening 720 disposed in the bottom chamber wall 260 of the processing module. Each sensor assembly 700 is disposed beneath the processing module 150. The opening 720 may be formed through the bottom chamber wall 260. The quartz window 714 is positioned at a bottom end 722 of the opening 720. A seal 725 may be disposed around the quartz window 714 as to maintain the integrity of the vacuum within the processing module 150. In operation, the laser sensor 710 transmit a laser L into the processing module 150 through the opening 720 and the quartz window 714 towards the shutter disk blade 172. If the shutter disk blade 172 is positioned above the laser L, the laser L is reflected back towards the laser sensor 710. Accordingly, the laser sensor 710 uses the reflection to determine the distanced between the laser sensor and the shutter disk blade 172, and thus whether the shutter disk blade 172 is positioned above the sensor assembly 700.

While the foregoing is directed to embodiments of the present disclosure, other and further embodiments of the disclosure may be devised without departing from the basic scope thereof, and the scope thereof is determined by the claims that follow.

What is claimed is:

1. A substrate processing module, comprising:
a transfer chamber having a sidewall and a bottom defining a transfer volume;
an array of processing stations disposed within the transfer volume, wherein each of the processing stations within the array are configured to selectively process at least one substrate;
at least one shutter disk assembly disposed in the transfer volume, the at least one shutter disk assembly comprising:
an actuator; and
a disk blade coupled to the actuator and configured to support a shutter disk, wherein the actuator is configured to rotate the disk blade between a first position and a second position; and
a substrate handling device disposed centrally within the transfer volume, the substrate handling device including a plurality of arms each configured to support and position a substrate under the processing stations within the array,
wherein, when the disk blade is in the first position, the disk blade is disposed between two of the plurality of processing stations, and wherein, when the disk blade is in the second position, the disk blade is located under one of the processing stations within the array.

2. The substrate processing module of claim 1, wherein the number of shutter disk assemblies is equal to the number of processing stations.

3. The substrate processing module of claim 2, wherein each of the at least one shutter disk assemblies is disposed between two of the processing stations of the array, and the substrate processing module further includes a lift assembly disposed within the transfer volume and configured to the selectively lift a substrate support into at least one of the processing stations.

4. The substrate processing module of claim 1, wherein the substrate handling device is a central transfer robot comprising:
an actuator;
a central support coupled to the actuator,
wherein, each of the plurality of arms is coupled to the central support, and each arm is configured to be selectively positioned between two of the array of processing stations.

5. The substrate processing module of claim 1, further comprising:
one or more sensors positioned to detect that the shutter disk blade is in the first position.

6. The substrate processing module of claim 5, further comprising one or more additional sensors positioned to detect that the shutter disk blade is in the second position.

7. The substrate processing module of claim 1, wherein the shutter disk assembly further comprises:
a coupler disposed on a motor;
an adapter coupled to the motor and disposed around the coupler; and
a feedthrough coupled to the adapter and a shaft, wherein the feedthrough is disposed within the adapter, and the shaft is coupled to the disk blade.

8. A substrate processing module, comprising:
a transfer chamber having a sidewall and a bottom defining a transfer volume;
a first processing assembly disposed within the transfer volume comprising:
a first substrate processing station;
a first shutter disk assembly disposed near the substrate processing station, the first shutter disk assembly comprising:
an actuator; and
a disk blade coupled to the actuator;
a first shutter disk storage area disposed near the shutter disk assembly and configured to house the disk blade and a shutter disk disposed thereon; and
a first plurality of sensor assemblies positioned to determine a rotational position of the shutter disk blade; and
a substrate handling device disposed centrally within the transfer volume, the substrate handling device including a plurality of arms each configured to position a substrate under the substrate processing station,
wherein the first disk blade is rotatable between a first position within the first shutter disk storage area and a second position located under the first substrate processing station.

9. The substrate processing module of claim 8, further including a second processing assembly disposed over the process volume, the second processing assembly comprising:
a second substrate processing station;
a second shutter disk assembly disposed near the substrate processing station, the second shutter disk assembly comprising:
a second actuator; and
a second disk blade coupled to the actuator;
a second shutter disk storage area disposed near the second shutter disk assembly configured to house the second disk blade having a shutter disk disposed thereon; and
a second plurality of sensor assemblies positioned to determine a rotational position of the second shutter disk blade;

10. The substrate processing module of claim 9, wherein the substrate handling device is configured to simultaneously position a first substrate under the first processing station and a second substrate under the second processing station.

11. The substrate processing module of claim 10, wherein the second disk blade is rotatable between a third position within the second shutter disk storage area and a fourth position located under the second substrate processing station.

12. The substrate processing module of claim 8, wherein the first shutter disk assembly further comprises:
a coupler disposed on the first actuator;
an adapter coupled to the first actuator and disposed around the coupler; and
a feedthrough coupled to the adapter and a shaft, wherein the feedthrough is disposed within the adapter, and the shaft is coupled to the disk first blade.

13. The substrate processing module of claim 9, wherein the each first and second disk blades comprises:
an arm portion coupled to the actuator;
a body portion proximate to the arm portion, the body portion configured to support the shutter disk; and
a notch extending from the body portion configured to engage with the shutter disk.

14. The substrate processing module of claim 9, wherein the first plurality of sensor assemblies and the second plurality of sensor assemblies each includes a laser sensor disposed below an opening formed in the bottom of the transfer chamber, wherein the laser sensor is configured to emit a detection laser through the opening into the transfer volume.

15. A method processing substrates, comprising:
placing a plurality of substrates within an array of processing stations disposed within a substrate processing module;
performing a physical vapor deposition process on the plurality of substrates within the array of processing stations;
moving the plurality of substrates from the processing stations of the array using a substrate handling device;
rotating at least one of a plurality of shutter disk assemblies from a first position to a second position below at least one of the processing stations;
performing a second process in the at least one of the processing stations; and
rotating the at least one of the shutter disk assemblies from the second position to the first position,
wherein the first position of each shutter disk assembly is located within a shutter disk storage area disposed within the substrate processing module.

16. The method of claim 15 further comprising:
determining the rotational position of the plurality of shutter disk assemblies by using a plurality of sensors disposed within the substrate processing module, wherein each of the plurality of shutter disk assemblies comprises:
an actuator; and
a disk blade coupled to the actuator,
wherein rotating each of the plurality of shutter disk assemblies comprises actuating the actuator to rotate the disk blade carrying the shutter disk between each of the shutter disk storage areas and the array of processing stations.

17. The method of claim 15, wherein moving the plurality of substrates comprises using the substrate handling device to simultaneously move the plurality of substrates from each processing stations of the array.

18. The method of claim 17, wherein rotating each of the plurality of shutter disk assemblies from the first position to the second position comprises simultaneously rotating each of the plurality of shutter disks to the second position.

19. The method of claim 15, wherein moving the plurality of substrates comprises using the substrate handling device to selectively move at least one of the plurality of substrates from at least one of the plurality of processing stations, wherein at least one of the plurality of substrates remains within one of the processing stations of the array.

20. The method of claim 19, wherein after at least one of the plurality of substrates has been moved from a corresponding processing station, moving the shutter disk assembly from the first position to the second position comprises selectively moving at least one of the plurality of the shutter disk assemblies from the shutter disk storage area to the processing station, wherein at least one of the plurality of shutter disks remains within the plurality of shutter disk storage areas.
